(19) United States
(12) Patent Application Publication
(10) Pub. No.: US 2026/0176763 A1
(43) Pub. Date: Jun. 25, 2026

(54) VARYING THICKNESS ISOLATION PLATE FOR USE IN SEMICONDUCTOR PROCESSING

(71) Applicant: Applied Materials, Inc., Santa Clara, CA (US)

(72) Inventors: Vedapuram S. ACHUTHARAMAN, Saratoga, CA (US); Srinivas D. NEMANI, Sunnyvale, CA (US); Ala MORADIAN, Sunnyvale, CA (US); Youngki CHANG, Santa Clara, CA (US)

(21) Appl. No.: 18/987,631

(22) Filed: Dec. 19, 2024

(51) Int. Cl. C23C 16/455

(52) U.S. Cl. CPC C23C 16/45589

(57) ABSTRACT

Embodiments of the present disclosure generally relate to a semiconductor processing chamber, and more particularly, an isolation plate having a geometry configured to improve a precursor deposition uniformity within a processing chamber, and related methods. In one or more embodiments, a substrate processing chamber includes a chamber body at least partially defining an internal volume. An upper window and a lower window are disposed within the internal volume. The upper window is at least partially defining a processing volume. A substrate support is disposed within the processing volume. An isolation plate is disposed between the substrate support and the upper window within the processing volume. The isolation plate includes a first face and a second face opposing the first face. At least one of the first face or the second face is at least partially curved.

### BACKGROUND

### Field

Embodiments of the present disclosure generally relate to a semiconductor processing chamber, and more particularly, an isolation plate having a geometry configured to improve a precursor deposition uniformity within a processing chamber, and related methods.

### Description of the Related Art

Semiconductor substrates are processed for a wide variety of applications, including the fabrication of integrated devices and micro-devices. One method of processing substrates includes depositing a material, such as a dielectric material or a semiconductive material, on an upper surface of the substrate. The material may be deposited in a lateral flow chamber by flowing a process gas parallel to the surface of a substrate positioned on a support, and thermally decomposing the process gas to deposit a material from the gas onto the substrate surface. However, during a deposition process, a vortex can form along the surface of the substrate due to substrate rotation. The vortex prevents a uniform process gas flow over the substrate, which affects the deposition quality and uniformity over the substrate. The vortex can be near a center of a processing volume, which can dominate gas flow and hinder deposition uniformity and device performance. The vortex can also make it difficult to adjust gas flow and/or processing.

Therefore, a need exists for improved process chamber components and related methods that facilitate depositing a material that is more uniform in thickness.

### SUMMARY

Embodiments of the present disclosure generally relate to a semiconductor processing chamber, and more particularly, an isolation plate having a geometry configured to improve a precursor deposition uniformity within a processing chamber, and related methods.

In one or more embodiments, a substrate processing chamber includes a chamber body at least partially defining an internal volume. An upper window and a lower window are disposed within the internal volume. The upper window is at least partially defining a processing volume. A substrate support is disposed within the processing volume. An isolation plate is disposed between the substrate support and the upper window within the processing volume. The isolation plate includes a first face and a second face opposing the first face. At least one of the first face or the second face is at least partially curved.

In one or more embodiments, a chamber kit for a substrate processing chamber includes an isolation plate including a first face and a second face opposing the first face. At least one of the first face or the second face is at least partially curved. The chamber kit further includes an actuator and an adjustment mechanism coupled to the actuator. The adjustment mechanism is configured to induce an angular movement in the isolation plate.

In one or more embodiments, a method of processing substrates, suitable for use in semiconductor manufacturing, includes heating a substrate positioned on a substrate support. The method further includes moving an isolation plate to adjust one or more of, a height of the isolation plate or an angle of the isolation plate such that the isolation plate moves to a non-parallel orientation relative to the substrate. The isolation plate includes a first face and a second face opposing the first face. At least one of the first face or the second face is at least partially curved. The method further includes flowing one or more process gases over the substrate to process the substrate. The flowing of the one or more process gases over the substrate includes guiding the one or more process gases through one or more flow paths defined at least in part by a space between the isolation plate and the substrate.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 is a partial schematic side cross-sectional view of a processing chamber, according to one or more embodiments.

FIG. 2 is a schematic top cross-sectional view of the processing chamber during a processing operation, according to one or more embodiments.

FIGS. 3A-3F are schematic side cross-sectional views of an isolation plate, according to embodiments.

FIG. 4 is a partial schematic side cross-sectional view of the processing chamber shown in FIG. 1, according to one or more embodiments.

FIG. 5A is a schematic partial perspective view of the flow guide insert, according to one or more embodiments.

FIGS. 5B and 5C are partial schematic side cross-sectional view of the flow guide insert 310, according to embodiments.

FIG. 6 is a partial schematic side cross-sectional view of an isolation plate and an adjustment mechanism, according to one or more embodiments.

FIG. 7 is a partial schematic side cross-sectional view of an isolation plate and an adjustment mechanism, according to one or more embodiments.

FIG. 8 is a partial schematic side cross-sectional view of an isolation plate and an adjustment mechanism, according to one or more embodiments.

FIG. 9 is a schematic block diagram view of a method of processing substrates, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure relates to a semiconductor processing chamber, and more particularly, an isolation plate having a geometry configured to improve a precursor deposition uniformity within a processing chamber, and related methods. In one or more embodiments, the isolation plate has a varying thickness. In such an embodiment, the varying thickness gradually increases in a radially inward direction. In one or more embodiments, the isolation plate has an outer face that is at least partially curved.

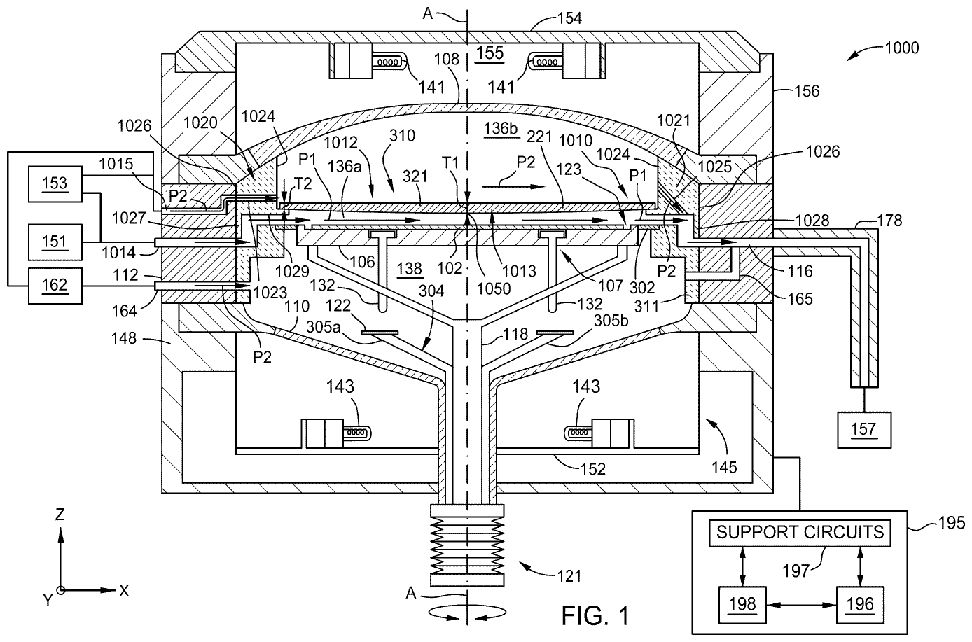

FIG. 1 is a partial schematic side cross-sectional view of a processing chamber 1000, according to one or more embodiments. The processing chamber 1000 is a deposition chamber. In one or more embodiments, the processing chamber 1000 is an epitaxial deposition chamber. The processing chamber 1000 is utilized to grow an epitaxial film on a substrate 102. The processing chamber 1000 creates a cross-flow of precursors across a top surface of the substrate 102. The processing chamber 1000 is shown in a processing condition in FIG. 1.

The processing chamber 1000 includes an upper body 156, a lower body 148 disposed below the upper body 156, a flow module 112 disposed between the upper body 156 and the lower body 148. The upper body 156, the flow module 112, and the lower body 148 form a chamber body. Disposed within the chamber body is a substrate support 106, an upper plate 108 (e.g., an upper window, such as an upper dome), a lower plate 110 (e.g., a lower window, such as a lower dome), a plurality of upper heat sources 141, and a plurality of lower heat sources 143. In one more embodiments, the upper plate 108, the lower plate 110, or a combination thereof is flat. The present disclosure contemplates that each of the heat sources described herein can include one or more of: lamp(s), resistive heater(s), light emitting diode(s) (LEDs), and/or laser(s). The present disclosure contemplates that other heat sources can be used. The present disclosure contemplates that the upper plate 108 and/or the lower plate 110 can be in the shape of a dome or can be in another shape, such as flat, concave, or another contour.

The substrate support 106 is disposed between the upper plate 108 and the lower plate 110. The substrate support 106 includes a support face 123 that supports the substrate 102. The plurality of upper heat sources 141 are disposed between the upper window and a lid 154. The plurality of upper heat sources 141 form a portion of the upper heat source module 155. The lid 154 may include a plurality of sensors disposed therein or thereon for measuring the temperature within the processing chamber 100. The plurality of lower heat sources 143 are disposed between the lower plate 110 and a floor 152. The plurality of lower heat sources 143 form a portion of a lower heat source module 145. In one or more embodiments, the upper plate 108 is an upper dome and is formed of an energy transmissive material, such as quartz. In one or more embodiments, the lower plate 110 is a lower dome and is formed of an energy transmissive material, such as quartz. A pre-heat ring 302 is disposed outwardly of the substrate support 106. The pre-heat ring 302 is supported on a ledge of the lower liner 311. A stop 304 includes a plurality of arms 305a, 305b that each include a lift pin stop 122 on which at least one of the lift pins 132 can rest when the substrate support 106 is lowered (e.g., lowered from a process position to a transfer position).

The internal volume has the substrate support 106 disposed therein. The substrate support 106 includes a top surface on which the substrate 102 is disposed. The substrate support 106 is attached to a shaft 118. The shaft 118 is connected to a motion assembly 121. The motion assembly 121 includes one or more actuators and/or adjustment devices that provide movement and/or adjustment for the shaft 118 and/or the substrate support 106.

The substrate support 106 may include lift pin holes 107 disposed therein. The lift pin holes 107 are sized to accommodate a lift pin 132 for lifting of the substrate 102 from the substrate support 106 either before or after a deposition process is performed.

An isolation plate 321 is disposed between the substrate support 106 and the upper plate 108. The isolation plate 321 includes a first face 1012 and a second face 1013 opposing the first face. The second face 1013 faces the substrate support 106. At least one of the first face 1012 or the second face 1013 is curved. The process chamber 1000 includes an upper liner 1020. The upper liner 1020 includes one or more inlet openings 1023 extending to an inner surface 1024 of the annular section 1021 on a first side of the upper liner 1020, and one or more outlet openings 1025 extending to the inner surface 1024 of the annular section 1021 on a second side of the upper liner 1020. It is contemplated in one or more embodiments, the isolation plate 321 is at least partially supported by the upper liner 1020. In one or more embodiments, the isolation plate 321 is formed of a transparent material, such as a transparent quartz. Other materials such as opaque materials (e.g., silicon carbide (SiC), graphite coated with SiC, and/or opaque quartz (such as white quartz, grey quartz, and/or black quartz)) are contemplated for the isolation plate 321.

The one or more inlet openings 1023 extend from an outer surface 1026 of the annular section 1021 of the upper liner 1020 to the inner surface 1024. The one or more outlet openings 1025 extend from a lower surface 1029 of the upper liner 1020 to the inner surface 1024. The upper liner 1020 includes a first extension 1027 and a second extension 1028 disposed outwardly of the lower surface 1029 of the upper liner 1020. A least part of the annular section 1021 of the upper liner 1020 is aligned with the first extension 1027 and the second extension 1028. In the embodiment shown in FIG. 1, a lowermost end of the isolation plate 321 is aligned above a lowermost end of the upper liner 1020. In one or more embodiments, as shown in FIG. 1, the lowermost end of the isolation plate 321 is part of the second face 1013, and the lowermost end of the upper liner 1020 is part of the first extension 1027 and/or the second extension 1028. The present disclosure contemplates that the lowermost end of the upper liner 1020 can be part of the lower surface 1029.

In one or more embodiments, the isolation plate 321 is in the shape of a disc, and the annular section 1021 is in the shape of a ring. The isolation plate 321 and the annular section 1021 are axially aligned around a center axis A. It is contemplated, however, that the isolation plate 321 and/or the annular section 1021 can be in the shape of a rectangle, or other geometric shapes. The isolation plate 321 at least partially fluidly isolates the upper portion 136b from the lower portion 136a. The isolation plate 321 includes at least one curved surface. The isolation plate 321 can include one or more openings (such as holes) that can fluidly connect the upper portion 136b and the lower portion 136a.

For example in FIG. 1, the isolation plate 321 has a convex architecture 221. The isolation plate 321 having a convex architecture 221 includes the first face 1012 and the second face 1013. The first face 1012 is flat. The second face 1013 has a convex curve. In one or more embodiments, the second face 1013 has a center of curvature 1050. In one or more embodiments, the center of curvature 1050 is concentric to the center axis A. In one or more embodiments, the center of curvature 1050 and the center of the substrate 102 are axially aligned. It is contemplated that the center of curvature 1050 can be offset from the center axis A. The isolation plate 321 having the convex architecture 221 has a varying thickness. The maximum thickness T1 of the isolation plate 321 having the convex architecture 221 is located at the center of curvature 1050. The thickness of the isolation plate 321 decreases when approaching the outer diameter of the isolation plate 321. The minimum thickness T2 of the isolation plate is located at the outer diameter of the isolation plate. The minimum thickness T2 is at least 1 mm, for example at least 2 mm, such as 5 mm, such as 10 mm. The distance between an upper surface of the substrate 102 and the second face 1013 of the isolation plate 321 is from about 1 mm to about 50 mm when substrate support 106 is in a raised processing position. The distance between the upper surface of the substrate 102 and the second face 1013 of the isolation plate 321 is a varying distance from about 1 mm to about 50 mm. In one or more embodiments, the thickness of the isolation plate 321 is a varying thickness from about 1 mm to about 30 mm, such as about 1 mm to about 15 mm, such as about 1 mm to about 10 mm. In one or more embodiments, the varying thickness is within a range of 1 mm to 3 mm at an outer region of the isolation plate 321 (e.g., for the minimum thickness T2), and the varying thickness is within a range of 10 mm to 15 mm at a central region of the isolation plate 321 (e.g., for the maximum thickness T1). The present disclosure contemplates that any varying thickness can be used for the isolation plate 321.

The flow module 112 (which can be at least part of one or more sidewalls of the processing chamber 1000) includes one or more first inlet openings 1014 in fluid communication with the lower portion 136a of the processing volume 136. The flow module 112 includes one or more second inlet openings 1015 in fluid communication with the upper portion 136b of the processing volume 136. The one or more first inlet openings 1014 are in fluid communication with one or more flow gaps between the upper liner 1020 and the lower liner 311. The one or more second inlet openings 1015 are in fluid communication with the one or more inlet openings 1023 of the upper liner 1020. The first inlet openings 1014 are fluidly connected to one or more process gas sources 151 and one or more cleaning gas sources 153. The purge gas inlet(s) 164 are fluidly connected to one or more purge gas sources 162. The one or more gas exhaust outlets 116 are fluidly connected to an exhaust pump 157. One or more purge gas outlets 165 are fluidly coupled to the exhaust pump 157 and the purge volume 138 to exhaust the one or more purge gases P2 from the purge volume 138. One or more process gases supplied using the one or more process gas sources 151 can include one or more reactive gases (such as one or more of silicon-containing, phosphorus-containing, and/or germanium-containing gases, and/or one or more carrier gases (such as one or more of nitrogen (N₂) and/or hydrogen (H₂)). One or more purge gases supplied using the one or more purge gas sources 162 can include one or more inert gases (such as one or more of argon (Ar), helium (He), and/or nitrogen (N₂)). One or more cleaning gases supplied using the one or more cleaning gas sources 153 can include one or more of hydrogen and/or chlorine. In one embodiment, which can be combined with other embodiments, the one or more process gases include silicon phosphide (SiP) and/or phosphine (PH₃), and the one or more cleaning gases include hydrochloric acid (HCl).

The one or more gas exhaust outlets 116 are further connected to or include an exhaust system 178. The exhaust system 178 fluidly connects the one or more gas exhaust outlets 116 and the exhaust pump 157. The exhaust system 178 can assist in the controlled deposition of a layer on the substrate 102. The exhaust system 178 is disposed on an opposite side of the processing chamber 100 relative to the flow module 112.

In one or more embodiments, as shown in FIG. 1, the one or more inlet openings 1023 are oriented in a horizontal orientation and the one or more outlet openings 1025 are oriented in an angled orientation. The present disclosure contemplates that the one or more inlet and/or outlet openings 1023, 1025 can be oriented in a horizontal orientation, oriented in an angled orientation, and/or can include one or more turns (such as the turns shown for the one or more first inlet openings 1014 and the one or more gas exhaust outlets 116).

During a deposition operation (e.g., an epitaxial growth operation), the one or more process gases P1 flow through the one or more first inlet openings 1014, through the one or more gaps, and into the lower portion 136a of the processing volume 136 to flow over the substrate 102. During the deposition operation, one or more purge gases P2 flow through the one or more second inlet openings 1015, through the one or more inlet openings 1023 of the upper liner 1020, and into the upper portion 136b of the processing volume 136. The one or more purge gases P2 flow simultaneously with the flowing of the one or more process gases P1. The flowing of the one or more purge gases P2 through the upper portion 136b facilitates reducing or preventing flow of the one or more process gases P1 into the upper portion 136b that would contaminate the upper portion 136b. The one or more process gases P1 are exhausted through gaps between the upper liner 1020 and the lower liner 311, and through the one or more gas exhaust outlets 116. The one or more purge gases P2 are exhausted through the one or more outlet openings 1025, through the same gaps between the upper liner 1020 and the lower liner 311, and through the same one or more gas exhaust outlets 116 as the one or more process gases P1. The present disclosure contemplates that that one or more purge gases P2 can be separately exhausted through one or more second gas exhaust outlets that are separate from the one or more gas exhaust outlets 116.

The present disclosure also contemplates that one or more purge gases can be supplied to the purge volume 138 (through the plurality of purge gas inlets 164) during the deposition operation, and exhausted from the purge volume 138.

As shown, a controller 195 is in communication with the processing chamber 1000 and is used to control processes and methods, such as at least some of the operations of the methods described herein.

The controller 195 is configured to receive data or input as sensor readings from a plurality of sensors. The sensors can include, for example: sensors that monitor growth of layer(s) on the substrate 102; sensors that monitor growth or residue on inner surfaces of chamber components of the processing chamber 1000 (such as inner surfaces of the upper plate 108 and/or the liners 1020, 311); sensors that monitor gas flow of the one or more process gases P1; and/or sensors that monitor temperatures of the substrate 102, the substrate support 106, the upper plate 108, the lower plate 110, the upper liner 1020, and/or the lower liner 311. The controller 195 is equipped with or in communication with a system model of the processing chamber 1000. The system model includes a heating model, a deposition model, a coating model, a rotational position model, and/or a gas flow model. The system model is a program configured to estimate parameters (such as a gas flow rate, an angular position of the plate 321, a height of the plate 321, a center-to-edge uniformity profile, a gas pressure, a processing temperature, a rotational position of component(s), a heating profile, a coating condition, and/or a cleaning condition) within the processing chamber 1000 throughout a deposition operation and/or a cleaning operation. The controller 195 is further configured to store readings and calculations. The readings and calculations include previous sensor readings, such as any previous sensor readings within the processing chamber 100. The readings and calculations further include the stored calculated values from after the sensor readings are measured by the controller 195 and run through the system model. Therefore, the controller 195 is configured to both retrieve stored readings and calculations as well as save readings and calculations for future use. Maintaining previous readings and calculations enables the controller 195 to adjust the system model over time to reflect a more accurate version of the processing chamber 1000.

The controller 195 can monitor, estimate an optimized parameter, adjust the angular position of the plate 321 and/or the height of the plate 321, detect a coating condition for the upper plate 108, generate an alert on a display, halt a deposition operation, initiate a chamber downtime period, delay a subsequent iteration of the deposition operation, initiate a cleaning operation, detect a cleaning condition for the upper plate 108, halt the cleaning operation, adjust a heating power, and/or otherwise adjust the process recipe.

The controller 195 includes a central processing unit (CPU) 198 (e.g., a processor), a memory 196 containing instructions, and support circuits 197 for the CPU 198. The controller 195 controls various items directly, or via other computers and/or controllers. In one or more embodiments, the controller 195 is communicatively coupled to dedicated controllers, and the controller 195 functions as a central controller.

The controller 195 is of any form of a general-purpose computer processor that is used in an industrial setting for controlling various substrate processing chambers and equipment, and sub-processors thereon or therein. The memory 196, or non-transitory computer readable medium, is one or more of a readily available memory such as random access memory (RAM), dynamic random access memory (DRAM), static RAM (SRAM), and synchronous dynamic RAM (SDRAM (e.g., DDR1, DDR2, DDR3, DDR3L, LPDDR3, DDR4, LPDDR4, and the like)), read only memory (ROM), floppy disk, hard disk, flash drive, or any other form of digital storage, local or remote. The support circuits 197 of the controller 195 are coupled to the CPU 198 for supporting the CPU 198. The support circuits 197 include cache, power supplies, clock circuits, input/output circuitry and subsystems, and the like. Operational parameters (e.g., a center-to-edge profile, an angular position of the plate 321, a height of the plate 321, the coating condition, a pressure for process gases P1, a processing temperature, a heating profile, a flow rate for process gases P1, a pressure for cleaning gases, a flow rate for cleaning gases, and/or a rotational position of the substrate support 106) and operations are stored in the memory 196 as a software routine that is executed or invoked to turn the controller 195 into a specific purpose controller to control the operations of the various chambers/modules described herein. The controller 195 is configured to conduct any of the operations described herein. The instructions stored on the memory, when executed, cause one or more of operations of method 900 (described below) to be conducted in relation to the processing chamber 100. The controller 195 and the processing chamber 1000 are at least part of a system for processing substrates.

The various operations described herein (such as the operations of the method 900) can be conducted automatically using the controller 195, or can be conducted automatically or manually with certain operations conducted by a user.

In one or more embodiments, the controller 195 includes a mass storage device, an input control unit, and a display unit. The controller 195 monitors the temperature of the substrate 102, the temperature of the substrate support 106, the temperature of the upper plate 108, the process gas flow, and/or the purge gas flow. In one or more embodiments, the controller 195 includes multiple controllers 195, such that the stored readings and calculations and the system model are stored within a separate controller from the controller 195 which controls the operations of the processing chamber 1000. In one or more embodiments, all of the system model and the stored readings and calculations are saved within the controller 195.

The controller 195 is configured to control the sensor devices, the deposition, the cleaning, the rotational position, the heating, and gas flow through the processing chamber 1000 by providing an output to the controls for the heat sources, the gas flow, and the motion assembly 121. The controls include controls for the sensor devices, the upper heat sources 141, the lower heat sources 143, the process gas source 151, the purge gas source 162, the motion assembly 121, and the exhaust pump 157.

The controller 195 is configured to adjust the output to the controls based on the sensor readings, the system model, and the stored readings and calculations. The controller 195 includes embedded software and a compensation algorithm to calibrate measurements. The controller 195 can include one or more machine learning algorithms and/or artificial intelligence algorithms that estimate optimized parameters for the deposition operations and/or the cleaning operations (such as for adjusting a deposition operation (e.g. the process recipe), halting the deposition operation, initiating a chamber downtime period, delaying a subsequent iteration of the deposition operation, initiating a cleaning operation, halting the cleaning operation, adjusting a heating power, and/or adjusting the cleaning operation). In one or more embodiments, the controller 195 includes one or more machine learning algorithms and/or artificial intelligence algorithms that estimate optimized parameters for determining an optimal tilt angle for the isolation plate 321. The optimized parameter can include, for example, a center-to-edge profile for the substrate 102 (which facilitates uniformity) with respect to temperature, gas flow rate, and/or deposition thickness.

The one or more machine learning algorithms and/or artificial intelligence algorithms may implement, adjust and/or refine one or more algorithms, inputs, outputs or variables described above. Additionally or alternatively, the one or more machine learning algorithms and/or artificial intelligence algorithms may rank or prioritize certain aspects of adjustments of the process chamber 1000 and/or the method 900 relative to other aspects of the process chamber 1000 and/or the method 900. The one or more machine learning algorithms and/or artificial intelligence algorithms may account for other changes within the processing systems such as hardware replacement and/or degradation. In one or more embodiments, the one or more machine learning algorithms and/or artificial intelligence algorithms account for upstream or downstream changes that may occur in the processing system due to variable changes of the process chamber 1000 and/or the method 900. For example, if variable “A” is adjusted to cause a change in aspect “B” of the process, and such an adjustment unintentionally causes a change in aspect “C” of the process, then the one or more machine learning algorithms and/or artificial intelligence algorithms may take such a change of aspect “C” into account. In such an embodiment, the one or more machine learning algorithms and/or artificial intelligence algorithms embody predictive aspects related to implementing the process chamber 1000 and/or the method 900. The predictive aspects can be utilized to preemptively mitigate unintended changes within a processing system.

The one or more machine learning algorithms and/or artificial intelligence algorithms can use, for example, a regression model (such as a linear regression model) or a clustering technique to estimate optimized parameters. The algorithm can be unsupervised or supervised. The one or more machine learning algorithms and/or artificial intelligence algorithms can optimize, for example, a heating power applied to the heat sources 141, 143, the angular position of the plate 321, and/or the height of the plate 321. The one or more machine learning algorithms and/or artificial intelligence algorithms can optimize, for example, a size and/or a shape of the lower portion 136a and/or the upper portion 136b using the angular position and/or the height of the plate 321.

The one or more machine learning algorithms and/or artificial intelligence algorithms can optimize, for example, a center-to-edge gas concentration profile across a substrate 102 during deposition operations. The center-to-edge gas concentration profile can be pre-generated using simulation operations, and the one or more machine learning algorithms and/or artificial intelligence algorithms can use real-time collected data to adjust the center-to-edge gas concentration profile. The center-to-edge concentration profile is affected, for example, by the size and/or the shape of the lower portion 136a.

In one or more embodiments, the controller 195 automatically conducts one or more operations described herein without the use of one or more machine learning algorithms or artificial intelligence algorithms. In one or more embodiments, the controller 195 compares measurements (such as of gas flow rate(s)) and/or deposition thickness to data in a look-up table and/or a library to determine if adjustment(s) can be used to facilitate a center-to-edge profile. The controller 195 can stored measurements as data in the look-up table and/or the library.

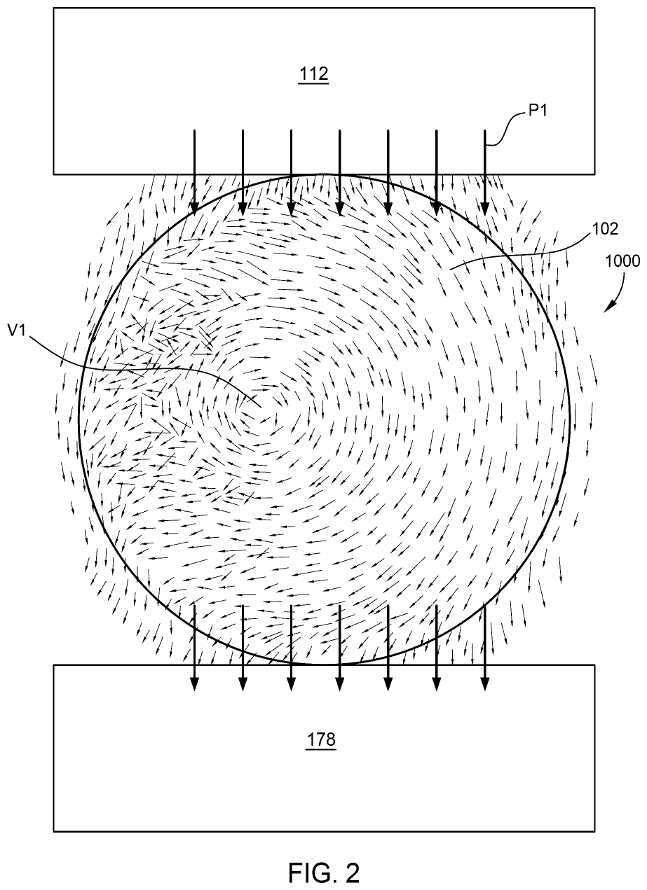

FIG. 2 is a schematic top cross-sectional view of the processing chamber 1000 during a processing operation, according to one or more embodiments. During a processing operation one or more process gases P1 flow from the flow module 112 across the substrate 102 and into the exhaust system 178. During the processing operation, the substrate support 106 is rotated about the axis A. The substrate support 106 rotates the substrate 102. The rotation of the substrate support 106 and the substrate 102 can cause the one or more process gases P1 to form a vortex V1 as the one or more process gases P1 flow across the substrate 102.

FIG. 2 is a processing chamber 1000 with the isolation plate 321 having at least the second face 1013 of the isolation plate 321 as curved. In one or more embodiments, the curved second face 1013 causes the vortex V1 to form closer to an outer edge of the substrate 102, rather than in the middle of the substrate 102. When the vortex V1 is formed near the outer edge of the substrate 102 flow of the one or more process gases P1 across the substrate 102 is more uniform and more adjustable. For example, subject matter described herein mitigates or prevents the vortex V1 from affecting the uniformity of gas flow. For example the subject matter mitigates or prevents the vortex V1 from dominating at least a region of flow. The isolation plate 321 having a curved second face 1013 improves the deposition uniformity across the substrate 102.

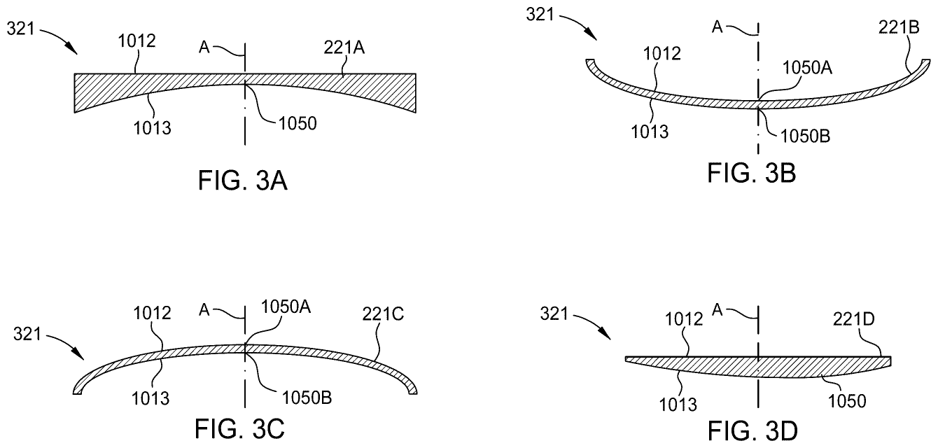

FIGS. 3A-3F are schematic side cross-sectional views of an isolation plate 321, according to embodiments. FIG. 3A shows an isolation plate 321 having a concave architecture 221A, according to one or more embodiments. The isolation plate 321 with the concave architecture 221A includes the first face 1012 and the second face 1013. The first face 1012 is flat. The second face 1013 has a concave curve. In one or more embodiments, the second face 1013 has a center of curvature 1050. In one or more embodiments, the center of curvature 1050 is concentric to the center axis A. In one or more embodiments, the center of curvature 1050 and the center of the substrate 102 are axially aligned. It is contemplated that the center of curvature 1050 can be offset from the center axis A. The isolation plate 321 having the convex architecture 221 has a varying thickness. The thickness of the isolation plate 321 having the convex architecture 221 has a minimum thickness at the center of curvature 1050 which increases when approaching the outer diameter of the isolation plate 321. The isolation plate has a minimum thickness of at least 1 mm, for example at least 2 mm, such as 5 mm, such as 10 mm.

FIG. 3B is an isolation plate 321 having a first curve architecture 221B, according to one or more embodiments. The isolation plate 321 with the first curve architecture 221B includes the first face 1012 and the second face 1013. The first face 1012 has a concave curve. The second face 1013 has a convex curve. In one or more embodiments, the first face 1012 has a first center of curvature 1050A. In one or more embodiments, the first center of curvature 1050A is concentric to the center axis A. In one or more embodiments, the second face 1013 has a second center of curvature 1050B. In one or more embodiments, the second center of curvature 1050B is concentric to the center axis A. In one or more embodiments, the centers of curvature 1050A, 1050B and the center of the substrate 102 are axially aligned. It is contemplated that either of the centers of curvature 1050A, 1050B can be offset from the center axis A. In one or more embodiments, the isolation plate 321 having the first curve architecture 221B has a uniform thickness of at least 1 mm, for example at least 2 mm, such as 5 mm, such as 10 mm.

FIG. 3C is an isolation plate 321 having a second curve architecture 221C, according to one or more embodiments. The isolation plate 321 with the second curve architecture 221C includes the first face 1012 and the second face 1013. The first face 1012 has a convex curve. The second face 1013 has a concave curve. In one or more embodiments, the first face 1012 has a first center of curvature 1050A. In one or more embodiments, the first center of curvature 1050A is concentric to the center axis A. In one or more embodiments, the second face 1013 has a second center of curvature 1050B. In one or more embodiments, the second center of curvature 1050B is concentric to the center axis A. In one or more embodiments, the centers of curvature 1050A, 1050B and the center of the substrate 102 are axially aligned. It is contemplated that either of the centers of curvature 1050A, 1050B can be offset from the center axis A. In one or more embodiments, the isolation plate 321 having the second curve architecture 221C has a uniform thickness of at least 1 mm, for example at least 2 mm, such as 5 mm, such as 10 mm.

FIG. 3D is an isolation plate 321 having an offset convex curve architecture 221D, according to one or more embodiments. The isolation plate 321 with the offset convex curve architecture 221D includes the first face 1012 and the second face 1013. The first face 1012 is flat. The second face 1013 has a convex curve. In one or more embodiments, the second face 1013 has a center of curvature 1050. The center of curvature 1050 is offset from the center axis A. In one or more embodiments, the center of curvature 1050 and the center of the substrate 102 are offset. The isolation plate 321 having the offset convex curve architecture 221D has a varying thickness. The thickness of the isolation plate 321 having the offset convex curve architecture 221D is the greatest at the center of curvature 1050 and decreases when approaching the outer diameter of the isolation plate 321. The isolation plate has a minimum thickness of at least 1 mm, for example at least 2 mm, such as 5 mm, such as 10 mm.

FIG. 3E shows an isolation plate 321 having a double convex curve architecture 221E, according to one or more embodiments. The isolation plate 321 with the double convex curve architecture 221E includes the first face 1012 and the second face 1013. The first face 1012 has a convex curve. The second face 1013 has a convex curve. In one or more embodiments, the first face 1012 has a first center of curvature 1050A. In one or more embodiments, the first center of curvature 1050A is concentric to the center axis A. In one or more embodiments, the second face 1013 has a second center of curvature 1050B. In one or more embodiments, the second center of curvature 1050B is concentric to the center axis A. In one or more embodiments, the centers of curvature 1050A, 1050B and the center of the substrate 102 are axially aligned. It is contemplated that one or both of the centers of curvature 1050A, 1050B can be offset from the center axis A. The isolation plate 321 having the double convex curve architecture 221E has a varying thickness. The thickness of the isolation plate 321 having the double convex curve architecture 221E is the greatest at the centers of curvature 1050a, 1050b and decreases when approaching the outer diameter of the isolation plate 321. The isolation plate 321 has a minimum thickness of at least 1 mm, for example at least 2 mm, such as 5 mm, such as 10 mm.

FIG. 3F shows an isolation plate 321 having a double concave curve architecture 221F, according to one or more embodiments. The isolation plate 321 with the double concave curve architecture 221F includes the first face 1012 and the second face 1013. The first face 1012 has a concave curve. The second face 1013 has a concave curve. In one or more embodiments, the first face 1012 has a first center of curvature 1050A. In one or more embodiments, the first center of curvature 1050A is concentric to the center axis A. In one or more embodiments, the second face 1013 has a second center of curvature 1050B. In one or more embodiments, the second center of curvature 1050B is concentric to the center axis A. In one or more embodiments, the centers of curvature 1050A, 1050B and the center of the substrate 102 are axially aligned. It is contemplated that one or both of the centers of curvature 1050A, 1050B can be offset from the center axis A. The isolation plate 321 having double concave curve architecture 221F has a varying thickness. The thickness of the isolation plate 321 having the double concave curve architecture 221F has a minimum thickness at the centers of curvature 1050a, 1050b which increases when approaching the outer diameter of the isolation plate 321. The isolation plate 321 has a minimum thickness of at least 1 mm, for example at least 2 mm, such as 5 mm, such as 10 mm.

The present disclosure contemplates that shapes and architectures other than concave and convex may be used. For example, tapered shapes and/or serpentine shapes may be used. Other shapes and architectures are contemplated.

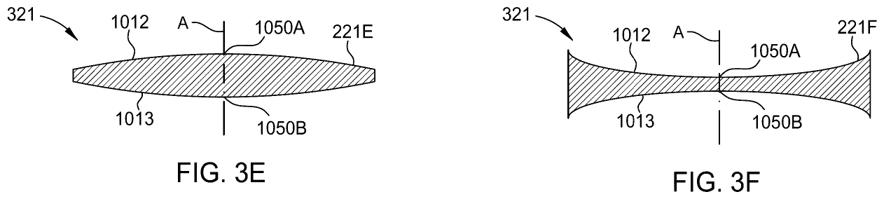

FIG. 4 is a partial schematic side cross-sectional view of the processing chamber 1000 shown in FIG. 1, according to one or more embodiments. The view in FIG. 4 is offset by an angle (such as 60-120 degrees, for example 90 degrees) from the view shown in FIG. 1.

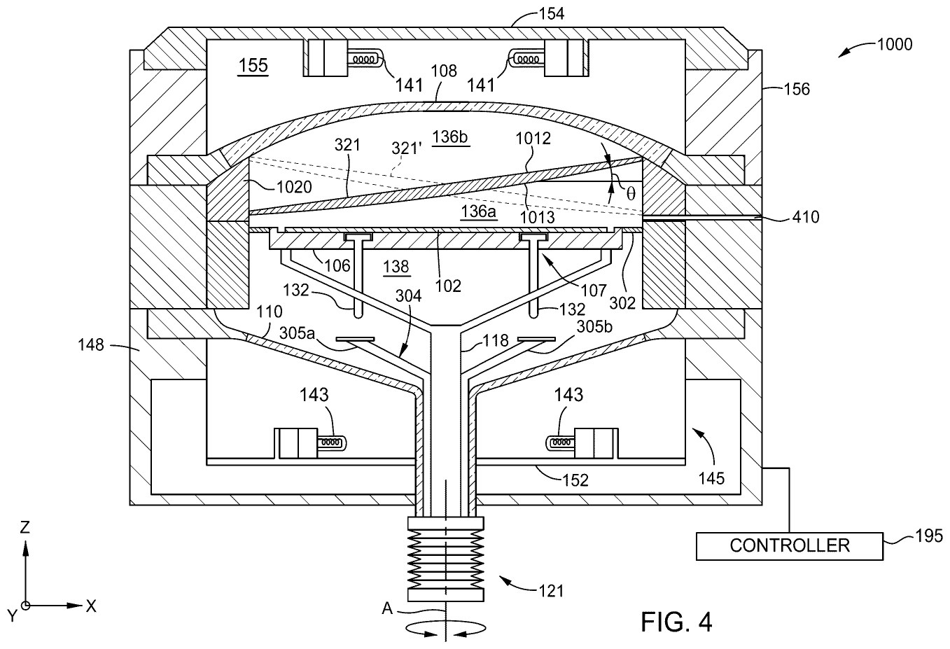

In one or more embodiments, the angle θ of the isolation plate 321 can be adjusted. Although the isolation plate 321 in FIG. 4 is shown having a convex architecture 221, it is contemplated that the isolation plate 321 can have any architecture, including the concave architecture 221A, the first curve architecture 221B, the second curve architecture 221C, or the offset convex curve architecture 221D. The angle θ of the isolation plate 321 can be adjusted to be offset up to 15 degrees in any direction. Additionally or alternatively, the isolation plate 321 can be moved to a position 321′ by adjusting the angle of the isolation plate 321. The position 321′ (shown in ghost) is tilted in an angular direction that is opposite of the tilted position shown in solid in FIG. 4. As such, the plate 321 can tilt in one or more of the opposite angular directions. By adjusting the angle θ of the isolation plate, the center of the vortex V1 to form closer to an outer edge of the substrate 102. By adjusting the angle θ of the isolation plate 321 the deposition uniformity across the substrate 102 is improved. FIGS. 5-8 are examples of different assemblies used to adjust the angle θ of the isolation plate 321. In one or more embodiments, an adjustment mechanism is coupled to the isolation plate 321. The adjustment mechanism is configured to induce an angular movement of the isolation plate 321.

The plane of the view in FIG. 4 intersects the plane of the view in FIG. 1 at a non-zero angle. In one or more embodiments, the isolation plate 321 pivots about a primary flow path (which extends into the page in FIG. 4) extending between the one or more gas inlets 114 and the one or more gas exhaust outlets 116. In FIG. 1 the one or more process gases p1 flow along the primary flow path. In one or more embodiments, the isolation plate 321 pivots (e.g., tilts) away from one or more intersection gas inlets 410 that supply one or more gases to the lower portion 136a, in addition to the primary flow of one or more process gases P1.

FIG. 5A is a schematic partial perspective view of the flow guide insert 310, according to one or more embodiments. Although the isolation plate 321 in FIG. 5A is shown having a convex architecture 221, it is contemplated that the isolation plate 321 can have any architecture, including the concave architecture 221A, the first curve architecture 221B, the second curve architecture 221C, or the offset convex curve architecture 221D.

The isolation plate 321 has a first side 322 (adjacent the gas inlets 114 in FIGS. 3 and 4) and a second side 323 opposing the first side 322 along a first direction D1. Each of the first side 322 and the second side 323 is arcuate.

In FIG. 5A, the flow guide insert 310 incudes the first parallel block 331 extending outwardly relative to a third side 324 of the isolation plate 321 and outwardly relative to an outer face 345 of the isolation plate 321, and a second parallel block 332 extending outwardly relative to a fourth side 325 of the isolation plate 321 and outwardly relative to the outer face 345 of the isolation plate 321. It is contemplated that the first parallel block 331 and the second parallel block 332 may be omitted from the flow guide insert 310 (as shown in FIGS. 1 and 2). In one or more embodiments where the parallel blocks 331 and 332 are omitted, the isolation plate 321 can be supported by the upper liner 1020 and/or the isolation plate 321 may be attached to the interior of the processing chamber via a pivot point or another attachment mechanism. The fourth side 325 opposes the third side 324 along a second direction D2 that intersects the first direction D1. In one or more embodiments, the second direction D2 is perpendicular to the first direction D1. The third side 324 and the fourth side 325 are linear. In one or more embodiments, the first and second parallel blocks 331, 332 are supported at least partially on the substrate support 106 such that raising and lowering of the substrate support 106 raises and lowers the flow guide insert 310 via the parallel blocks 331, 332. A rectangular flow opening 350 is defined between a first planar inner face 333 of the first parallel block 331 and a second planar inner face 334 of the second parallel block 332. Each of the first parallel block 331 and the second parallel block 332 is semi-circular in shape. In one or more embodiments, the isolation plate 321 is formed of quartz and the first and second parallel blocks 331, 332 are each formed of silicon carbide (SiC). The rectangular flow opening 350 has a 3-D rectangular box shape such that the rectangular flow opening 350 has a rectangular shape in the X-Y plane, the X-Z plane, and/or the Y-Z plane. When the flow guide insert 310 is in the processing position, the rectangular flow opening 350 is defined by one or more of the first planar inner face 333, the second planar inner face 334, an upper surface of the substrate 102, an upper surface of the substrate support 106, and/or an upper surface of the pre-heat ring 302.

It is contemplated that in embodiments with the first and second parallel blocks 331, 332, the size of the parallel blocks may be varied to increase or decrease the lower portion 136a of the processing volume 136. It is also contemplated that the first and second parallel blocks 331, 332 may include actuating supports configured to mechanically move the isolation plate 321 up and down.

In or more embodiments, it is contemplated that upper and lower interfacing surfaces of the isolation plate 321 and the first and second parallel blocks 331, 332 may be curved and having matching radii of curvature (e.g., are semicircular). The interfacing curved surfaces allow rotation of the isolation plate 321 relative to the first and second parallel blocks 331, 332 while preventing airflow between the interface of the isolation plate 321 relative to the first and second parallel blocks 331, 332.

The one or more process gases P1 flow through the rectangular flow opening 350 when flowing through the lower portion 136a and over the substrate 102. The rectangular flow opening 350 facilitates adjustability of process gases, purge gases, and/or cleaning gases (such as pressure and flow rate), to facilitate process uniformity and deposition uniformity while providing a path for cleaning gases to the upper portion 136b. As an example, the rectangular flow opening 350 facilitates using high pressures and low flow rates for the process gases and the cleaning gases. The rectangular flow opening 350 also facilitates mitigation of the effects that rotation of the substrate 102 has on process uniformity and film thickness uniformity during a deposition operation. As an example, the rectangular flow opening mitigates or removes the effects of gas vortex.

FIGS. 5B and 5C are partial schematic side cross-sectional view of the flow guide insert 310, according to embodiments. Although the isolation plate 321 is shown having a convex architecture 221, it is contemplated that the isolation plate 321 can have any architecture, including the concave architecture 221A, the first curve architecture 221B, the second curve architecture 221C, or the offset convex curve architecture 221D.

FIG. 5B is a flow guide insert 310 wherein the first parallel block 331 and the second parallel block 332 have different heights. In one or more embodiments, the first parallel block has a first height H1 defined by the distance from an upper face 355 of the first parallel block 331 to a lower face 359 of the first parallel block 331. The second parallel block has a second height H2 defined by the distance from an upper face 356 of the second parallel block 332 to a lower face 360 of the second parallel block 332. The first height H12 and the second height H2 are different from one another so that the isolation plate 321 is supported at an angle θ as shown in FIG. 4. The isolation plate 321 being supported at the angle θ can prevent the vortex V1 from forming in the center of the substrate 102.

FIG. 5C is a flow guide insert 310 wherein the first parallel block 331, the second parallel block 332, or a combination thereof have a sloped lower face. In one or more embodiments, the first parallel block 331 has a minimum height H3 at the first planar inner face 333. The lower face 359 of the first parallel block 331 has a gradient so that the maximum height H4 of the first parallel block 331 is at an outer face 357 of the first parallel block 331. The second parallel block 332 has a minimum height H5 at its outer face 358. The lower face 360 of the second parallel block 332 has a gradient so that the maximum height H6 of the second parallel block 332 is at the second planar inner face 334 of the second parallel block 332. The sloped lower face 359 of the first parallel block 331 and the sloped lower face 360 of the second parallel block 332 tilt the isolation plate 321 is supported at an angle θ as shown in FIG. 4. The isolation plate 321 being supported at the angle θ prevents the vortex V1 from forming in the center of the substrate 102. The tilting of the isolation plate 321 can, for example, change a flow conductance area to adjust processing.

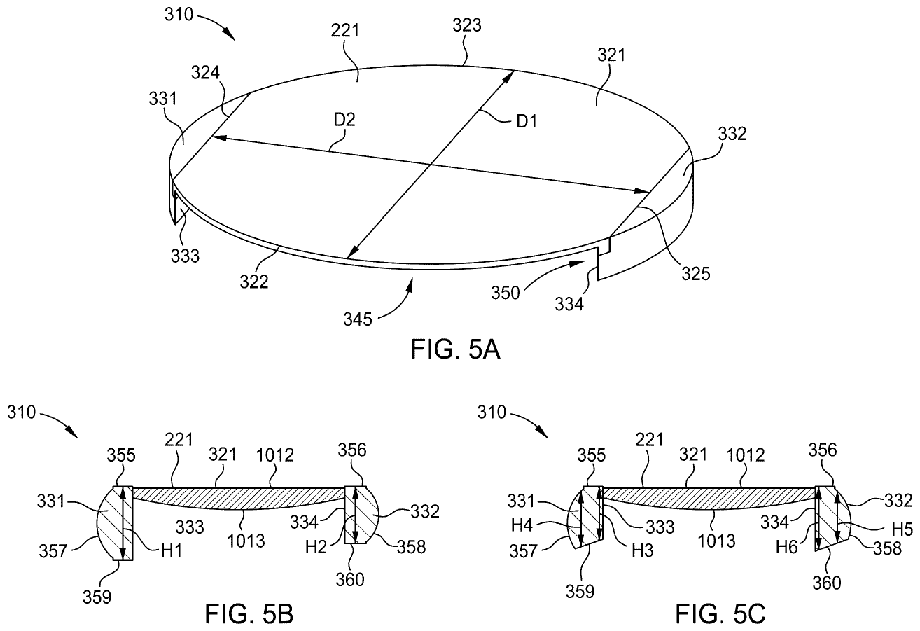

FIG. 6 is a partial schematic side cross-sectional view of an isolation plate 321 and an adjustment mechanism 600, according to one or more embodiments. Although the isolation plate 321 is shown having a convex architecture 221, it is contemplated that the isolation plate 321 can have any architecture, including the concave architecture 221A, the first curve architecture 221B, the second curve architecture 221C, or the offset convex curve architecture 221D.

The isolation plate 321 and adjustment mechanism 600 may be utilized in the processing chamber 1000. The adjustment mechanism 600 facilitates adjustment of a plane of the isolation plate 321, relative to a plane of the substrate support 106 and/or substrate 102. Adjustment of the orientation of the plane of the isolation plate 321 relative to a plane of the substrate 102 changes the relative distances between portions of the isolation plate 321 and the substrate 102. The adjustment of the orientation of the isolation plate prevents the vortex V1 from forming over the center of the substrate 102. These changes can result in more uniform processing (e.g., deposition of more uniform film thickness) across the substrate 102.

In FIG. 6, the adjustment mechanism 600 includes a pivot shaft 670, about which a plane of the isolation plate 321 rotates. In one or more embodiments, the pivot shaft 670 is located in the center 680 of the processing chamber 1000 (e.g., equidistant from a gas inlet and gas outlet of the processing chamber 1000 or perpendicular to a flow path of process gases over the substrate 102). Thus, in one or more embodiments, adjustments to the isolation plate 321 result in equal (e.g., absolute) changes in plate position at a first edge of the isolation plate (e.g., +X mm) and a second edge of the isolation plate 321 (e.g., −X mm). It is contemplated that the pivot shaft 670 may not be positioned at a center of the processing chamber or the isolation plate.

For reference, the upper liner 1020 is shown in FIG. 6. The upper liner 1020 may optionally include a concave surface 6024 on a radially inward surface thereof. The concave surface 6024 is sized to maintain a predetermined distance between the distal ends of the isolation plate 321 and the upper liner 1020 as the isolation plate 321 is rotated. Thus, gas escapement between the isolation plate 321 and the upper liner 1020 is reduced. It is contemplated that concave surface 6024 can extend substantially around the entire inner surface of the upper liner 1020.

The pivot shaft 670 is disposed within the upper liner 1020, and rotatable within a receptacle thereof. In one or more embodiments, the pivot shaft 670 may be received within a bearing sleeve housed within the upper liner 1020 to facilitate pivoting (such as rotation). An actuator 671 is coupled to the pivot shaft 670 to induce movement. The actuator may be, for example, a stepper motor, a pneumatic actuator, or the like. Additionally, while one pivot shaft 670 is shown, it is contemplated that the isolation plate 321 may include a second pivot shaft opposite the first pivot shaft (e.g., spaced 180 degrees therefrom) to provide increased support to the isolation plate.

The adjustment mechanism 600 includes lock pins 660a, 660b, 660c. In one or more embodiments, the adjustment mechanism may include more or fewer lock pins 660a, 660b, 660c. The positions of the lock pins 660a, 660b, 660c determine an adjusted position 321a of the isolation plate 321. In one or more embodiments, the positions of the lock pins 660a, 660b, 660c may be determined based on the position of the isolation plate 321 relative to a substrate 102. In one or more embodiments, it is contemplated that the isolation plate 321 is mounted to a pivot shaft 670, and an optional lock pin 660a, 660b, 660c is inserted into the upper liner 1020 based on the desired angle of the isolation plate 321, in order to secure the isolation plate 321 into position. The isolation plate 321 rests on the inserted lock pin 660a, 660b, 660c. It is also contemplated that the lock pins 660a, 660b, 660c are located on a mechanism that locks the angle of the isolation plate. In one or more embodiments, a wheel is located around the pivot shaft 670 that has holes therein for insertion of the lock pins 660a, 660b, 660c.

As shown in FIG. 6, the adjustment mechanism 600 enables a clockwise rotation 666 of the isolation plate 321. In one or more embodiments, the adjustment mechanism 600 enables counterclockwise rotation, and/or both clockwise and counterclockwise rotation. Circle 664 illustrates the extent that the isolation plate 321 may be rotated, wherein circle 664 is bisected by the center 680 of the processing chamber 1000. It is contemplated that a vertical position of a substrate support may be adjusted, as needed, to accommodate positioning of the isolation plate 321. In one or more embodiments, the isolation plate 321 is capable of a maximum of ±45° of rotation, such as a maximum of ±30° of rotation. In one or more embodiments, the isolation plate 321 is capable of a maximum of ±5° of rotation. In one or more embodiments, the isolation plate 321 is capable of a maximum of ±3.5° of rotation.

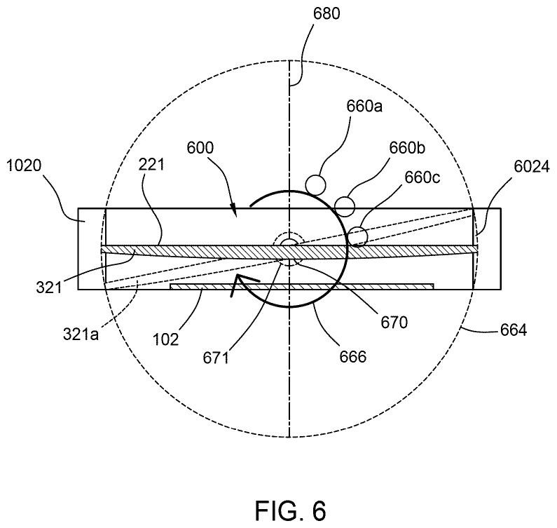

FIG. 7 is a partial schematic side cross-sectional view of an isolation plate 321 and an adjustment mechanism 700, according to one or more embodiments. Although the isolation plate 321 is shown having a convex architecture 221, it is contemplated that the isolation plate 321 can have any architecture, including the concave architecture 221A, the first curve architecture 221B, the second curve architecture 221C, or the offset convex curve architecture 221D.

The isolation plate 321 and adjustment mechanism 700 may be utilized in the processing chamber 100. The adjustment mechanism 700 is similar to the adjustment mechanism 600, and the isolation plate 321 pivots at a distal end thereof instead of at a midpoint thereof. In one or more embodiments, the isolation plate 321 can pivot at the endpoint such that the moving of the isolation plate 321 results in approximately no change in a height (e.g., a change of 1.0 mm or less, such as 0.5 mm or less) of a first end of the isolation plate 321.

In FIG. 7, the adjustment mechanism 700 includes a pivot shaft 770. The pivot shaft 770 is located adjacent a gas inlet or gas outlet of the processing chamber, and supports the isolation plate 321 in a cantilevered manner. The pivot shaft 770 is coupled to the upper liner 1020, and actuated by an actuator 771. In the example of FIG. 7, the distance between the isolation plate 321 and substrate 102 changes to a lesser degree near the pivot shaft 770 compared to the distance between the isolation plate 321 and substrate 102 at an end opposite the pivot shaft 770 (as shown by the adjusted position 321a of the isolation plate 321). Thus, in one or more embodiments, gas velocity is differentially adjusted across the surface of the substrate 102 by the changing distance between the substrate 102 and the isolation plate 321.

As shown in FIG. 7, the adjustment mechanism 700 enables a clockwise rotation 766 of the isolation plate 321. In one or more embodiments, the adjustment mechanism 700 may enable counterclockwise rotation, or both clockwise and counterclockwise rotation. The adjustment mechanism 700 may be rotated more or less depending on the desired angle between the isolation plate 321 and the substrate 102. The pivot shaft 770 may rotate via actuator 771, manual operation, or other forms of inducing rotation. Features of the adjustment mechanism 700 of FIG. 7 may be used in combination with features of the adjustment mechanism 600 of FIG. 6. The outer edge of the isolation plate 321 travels along a concave surface 6024 of the upper liner 1020 to reduce gas flow between the isolation plate 321 and the upper liner 1020 due to rotation of the isolation plate 321. In one or more embodiments, the isolation plate 321 may be capable of a maximum of ±45° of rotation, such as a maximum of ±30° of rotation. In one or more embodiments, the isolation plate 321 may be capable of a maximum of ±5° of rotation. In one or more embodiments, the isolation plate 321 may be capable of a maximum of ±3.5° of rotation.

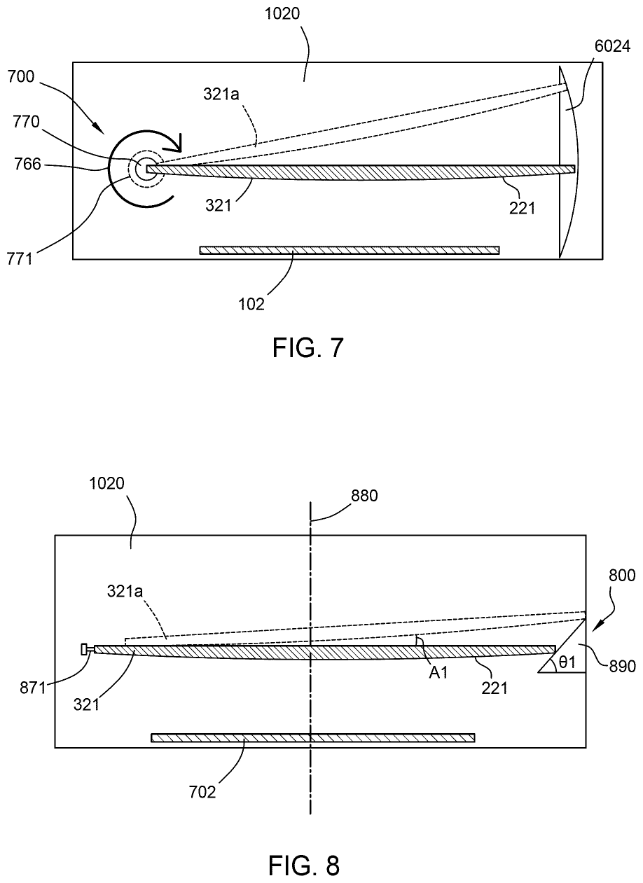

FIG. 8 is a partial schematic side cross-sectional view of an isolation plate 321 and an adjustment mechanism 800, according to one or more embodiments. The isolation plate 321 and adjustment mechanism 800 may be utilized in the processing chambers 1000. Although the isolation plate 321 is shown having a convex architecture 221, it is contemplated that the isolation plate 321 can have any architecture, including the concave architecture 221A, the first curve architecture 221B, the second curve architecture 221C, or the offset convex curve architecture 221D.

In FIG. 8, the adjustment mechanism 800 includes a ramp 890 and an actuator 871 for guiding the isolation plate 321 up the ramp 890. Movement of the isolation plate 321 along the ramp surface changes an orientation of the plane of the isolation plate 321. As shown in FIG. 8, the ramp 890 may be located on an inner surface of the upper liner 1020, opposite an actuator 871. In other embodiments, the ramp 890 may be located in other positions such that movement of the isolation plate 321 by the actuator 871 along a surface of the ramp 890 results in a change of the planar orientation of the isolation plate 321 relative to a plane of the substrate 102 to adjust an angle of a plane of the isolation plate 821 relative to the plane of the substrate 102. In one or more embodiments, the isolation plate 321 is moved to a non-parallel orientation relative to the substrate 102. For example, a plane (such as a plane of a lower surface) of the isolation plate 321 can be pivoted (such as rotated) to intersect a plane (such as a plane of an upper surface) of the substrate 102 at an intersection angle A1 that is 3 degrees or larger, such as 5 degrees or larger. In one or more embodiments, the angle A1 is within a range of 0 degrees to 15 degrees.

As shown in FIG. 8, the ramp 890 has an angle θ1. The angle θ1 may be larger or smaller based on a desired adjusted position 321a of the isolation plate 321. In one or more embodiments, the angle θ1 ranges from 0° to 15°. In one or more embodiments, the angle θ1 is about equal to the angle A1. The present disclosure contemplates that the angle A1 can be different from the angle θ1. In one or more embodiments, the upper surface of the ramp 890 may be curved (e.g., non-linear) to facilitate graduated adjustment of the isolation plate 321 as the isolation plate 321 moves along the ramp 890. The amount that the isolation plate 321 is pushed up the ramp 890 may vary based on the desired adjusted position 321a of the isolation plate 321. The isolation plate 321 may be pushed up the ramp 890 via the actuator 871, or other forms of inducing movement. Features of the adjustment mechanism 800 of FIG. 8 may be used in combination with features of the adjustment mechanism 600 of FIG. 6, or the adjustment mechanism 700 of FIG. 7.

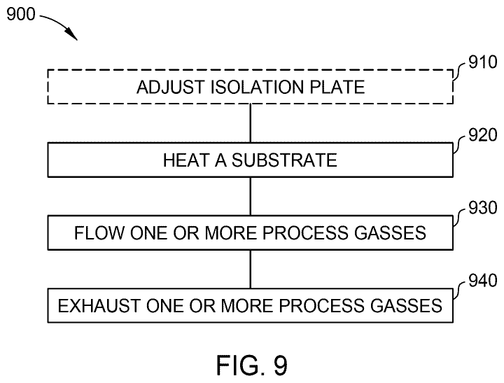

FIG. 9 is a schematic block diagram view of a method 900 of processing substrates, according to one or more embodiments.

Optional operation 910 includes adjusting an isolation plate within a processing chamber. Operation 910 may be performed, for example, via the adjustment mechanisms 600, 700, 800. The isolation plate may be adjusted up, down, and/or at an angle. In one or more embodiments, the adjusting includes moving the isolation plate to adjust one or more of: a height of the isolation plate, or an angle of the isolation plate such that the isolation plate moves to a non-parallel orientation relative to the substrate.

In one or more embodiments, the isolation plate is adjusted to more uniformly deposit a layer on the substrate. In one or more embodiments, the isolation plate is adjusted to decrease the time for a cleaning operation. In one or more embodiments, the isolation plate may be adjusted based on the specific process gases utilized in operation 930. Operation 910 may be performed prior to, simultaneously with, and/or after operations 920, 930, 940. It is contemplated that a position of the isolate plate may be empirically determined, modeled, and/or derived via metrology data obtained during processing. A controller (such as the controller 195) may store instructions that control an actuator to adjust the isolation plate in order to achieve target (such as predetermined) process results.

In one or more embodiments, the isolation plate is adjusted so a vortex is prevented from forming over the center the substrate. The adjustment of the isolation plate instead pushes the vortex towards an outer edge of the substrate which results in increased deposition uniformity.

Operation 920 includes heating a substrate positioned on a substrate support. Operation 920 may be performed prior to, simultaneously with, and/or after operation 910. Heating occurs via a plurality of heat sources (such as radiant heat sources), and to a predetermined temperature, as described above.

Operation 930 includes flowing one or more process gases over the substrate to form one or more layers on the substrate. The flowing of the one or more process gases over the substrate includes optionally guiding the one or more process gases through a rectangular flow opening of a flow guide insert. In one or more embodiments, the one or more process gases are supplied at a pressure that is 1 Torr or greater, such as within a range of 1 Torr to 600 Torr (e.g., 10 Torr to 600 Torr), or greater. Other pressures such as less than 1 Torr, for example 100 mTorr or less, may be used. In one or more embodiments, the one or more process gases are supplied at a flow rate that is less than 5,000 standard cubic centimeters per minute (SCCM). In one or more embodiments, the substrate is rotated at a rotation speed that is less than 64 rotations-per-minute, such as less than 32 rotations-per-minutes, for example less than 16 rotations-per-minute (RPM) during the flowing of the one or more process gases over the substrate. In one or more embodiments, the rotation speed is 1 RPM. Other flow rates and rotation speeds (such as 32 RPM) are contemplated.

Operation 940 includes exhausting the one or more process gases through an exhaust path formed at least partially in a sidewall.

Other processes may be performed before, during, or after the completion of the method 900. In one or more embodiments, purge gases may be flowed through the processing chamber during method 900. In one or more embodiments, cleaning gas may be flowed through the processing chamber after the completion of method 900.

Benefits of the present disclosure include mitigated effects of vortex flow, and/or movement of the vortex away from a center of a substrate being processed. Mitigating and/or moving a vortex relative to the center of a substrate facilitates enhanced processing (e.g., deposition) thicknesses; enhanced processing (e.g., deposition) uniformities; reduced coating of chamber components (such as the isolation plate 321); adjustability of process parameters (such gas flow rate, temperature, and/or growth rate); reduced cleaning; increased throughput and efficiency; and reduced chamber downtime. As an example, it is believed that the subject matter herein can move a center of a vortex from about 30 mm from a center of a substrate to about 50 mm from the center of the substrate. As another example, it is believed that the subject matter herein can improve deposition uniformity by about 35-40%.

It is contemplated that one or more aspects disclosed herein may be combined. As an example, one or more aspects, features, components, operations and/or properties of the processing chamber 1000, the isolation plate 321, the first face 1012, the second face 1013, the convex architecture 221, the concave architecture 221A, first curve architecture 221B, the second curve architecture 221C, offset convex curve architecture 221D, the double convex curve architecture 221E, the double concave curve architecture 221F, the flow guide insert 310, the first parallel block 331, the second parallel block 332, the adjustment mechanism 600, adjustment mechanism 700, adjustment mechanism 800, and/or the method 900 may be combined. Moreover, it is contemplated that one or more aspects disclosed herein may include some or all of the aforementioned benefits.

While the foregoing is directed to embodiments of the present disclosure, other and further embodiments of the disclosure may be devised without departing from the basic scope thereof, and the scope thereof is determined by the claims that follow.

What is claimed is:

1. A substrate processing chamber, comprising:
a chamber body at least partially defining an internal volume;
an upper window and a lower window disposed within the internal volume, the upper window at least partially defining a processing volume;
a substrate support disposed within the processing volume; and
an isolation plate disposed between the substrate support and the upper window within the processing volume, the isolation plate comprising a first face and a second face opposing the first face, wherein at least one of the first face or the second face is at least partially curved.

2. The substrate processing chamber of claim 1, wherein the second face has a convex curve.

3. The substrate processing chamber of claim 1, wherein and the second face has a concave curve.

4. The substrate processing chamber of claim 1, wherein the first face has a concave curve and the second face has a convex curve.

5. The substrate processing chamber of claim 1, wherein the first face has a convex curve and the second face has a concave curve.

6. The substrate processing chamber of claim 1, wherein the first face and the second face have a convex curve.

7. The substrate processing chamber of claim 1, wherein the first face and the second face have a concave curve.

8. The substrate processing chamber of claim 1, wherein the isolation plate comprises a quartz material, and the isolation plate has a thickness of at least 1 mm.

9. The substrate processing chamber of claim 1, wherein the isolation plate has a varying thickness that varies within a thickness range of 1 mm to 30 mm.

10. The substrate processing chamber of claim 9, wherein the varying thickness is within a range of 1 mm to 3 mm at an outer region of the isolation plate, and the varying thickness is within a range of 10 mm to 15 mm at a central region of the isolation plate.

11. The substrate processing chamber of claim 10, wherein the varying thickness gradually increases in a radially inward direction from the outer region and toward the central region.

12. The substrate processing chamber of claim 1, wherein a distance between the second face of the isolation plate and an upper surface of the substrate support is within a range of 1 mm to 50 mm.

13. The substrate processing chamber of claim 1, wherein a distance between the second face of the isolation plate and an upper surface of the substrate support is within a range of 1 mm to 7 mm at an outer region of the isolation plate, and the distance is within a range of 11 mm to 15 mm at a central region of the isolation plate.

14. A chamber kit for a substrate processing chamber comprising:
an isolation plate comprising a first face and a second face opposing the first face, at least one of the first face or the second face is at least partially curved;
an actuator; and
an adjustment mechanism coupled to the actuator, the adjustment mechanism configured to induce an angular movement in the isolation plate.

15. A processing chamber comprising:
the chamber kit of claim 14, wherein the adjustment mechanism comprises a pivot shaft; and
a chamber body having one or more gas inlets and one or more gas exhaust outlets, the one or more gas inlets and the one or more gas exhaust outlets defining a first plane therebetween,
wherein the angular movement tilts the isolation plate in a second plane oriented to intersect the first plane at a non-zero angle.

16. The chamber kit of claim 14, wherein the isolation plate comprises a quartz material, and the isolation plate has a thickness of at least 1 mm.

17. A method of processing substrates, suitable for use in semiconductor manufacturing, the method comprising:
heating a substrate positioned on a substrate support;
moving an isolation plate to adjust one or more of:
a height of the isolation plate, or
an angle of the isolation plate such that the isolation plate moves to a non-parallel orientation relative to the substrate, wherein the isolation plate comprises a first face and a second face opposing the first face, wherein at least one of the first face or the second face is at least partially curved; and
flowing one or more process gases over the substrate to process the substrate, the flowing of the one or more process gases over the substrate comprising guiding the one or more process gases through one or more flow paths defined at least in part by a space between the isolation plate and the substrate.

18. The method of claim 17, wherein the moving of the isolation plate comprises angling the isolation plate using a pivot shaft, wherein the pivot shaft is coupled to the isolation plate.

19. The method of claim 18, wherein the pivot shaft is located at an end of the isolation plate.

20. The method of claim 17, where the moving of the isolation plate comprises sliding an end of the isolation plate up a ramp.
